(19) United States
(12) Patent Application Publication
(10) Pub. No.: US 2005/0020003 A1
(43) Pub. Date: Jan. 27, 2005

(54) Semiconductor process and integrated circuit

(76) Inventors: Ted Johansson, Djursholm (SE); Hans Norstrom, Solna (SE); Patrik Algotsson, Stockholm (SE)

Correspondence Address: Baker Botts L L P, One Shell Plaza, 910 Louisiana, Houston, TX, 77002-4995, US

(21) Appl. No.: 10/699,222

(22) Filed: Oct. 31, 2003

Related U.S. Application Data
(63) Continuation of application No. PCT/SE02/00838, filed on Apr. 29, 2002.

(30) Foreign Application Priority Data
May 4, 2001 (SE) 0101567-6
Sep. 13, 2001 (SE) 0103036-0

(51) Int. Cl. H01L 21/8238

(52) U.S. Cl. 438/207

(57) ABSTRACT

An IC fabrication method comprises the steps of: providing a substrate (10, 41); forming an active region (41) for a bipolar transistor and an active region (41) for a MOS device in the substrate (10); forming isolation areas (81) around, in a horizontal plane, the active regions; forming a MOS gate region (111, 112) on the active region for the MOS device; forming a layer (141) of an insulating material on the MOS gate region and on the active region (31) for the transistor; and defining a base region in the active region for the transistor by producing an opening (143) in the insulating layer (141) such that the remaining portions of the insulating layer (141) partly cover the active region for the bipolar transistor. The insulating layer (141) remains on the MOS gate region to encapsulate and protect the MOS gate region during subsequent manufacturing steps.

### CROSS REFERENCE TO RELATED APPLICATION

This application is a continuation of copending International Application No. PCT/SE02/00838 filed Apr. 29, 2002, and claiming a priority date of Apr. 5, 2001, which designates the United States.

### TECHNICAL FIELD OF THE INVENTION

The present invention generally relates to the field of silicon IC-technology, and more specifically to the integration of active and passive devices in a process flow, especially designed for bipolar RF-IC's.

### BACKGROUND OF THE INVENTION

Advanced silicon bipolar, CMOS or BiCMOS circuits are used today for high-speed applications in the 1-5 GHz frequency range, replacing circuits previously only possible to realize using III-V based technologies. Their major application area is for modern telecommunication systems. The circuits are used mostly for analog functions, e.g. for switching currents and voltages, and for high-frequency radio functions, e.g. for mixing, amplifying, and detecting functions.

To obtain transistors well suited for e.g. telecommunication applications, not only a low transit time (high f_{T}) is needed, but also a high maximum oscillation frequency (fₘₐₓ) and good linearity are required. To obtain this, the transistor must not only have a short and well-optimized vertical structure, but the internal parasitics, which mainly consists of collector-base capacitance and base resistance, must also be very low. Because of the electrons high mobility, the main element for circuit design is the NPN-transistor. The process is thus designed with a primary purpose to obtain NPN-transistors exhibiting optimal characteristics.

To facilitate circuit design, some kind of p-type device is also needed. It is possible to add high-performing PNP-transistors to the process designed according to the principles described above, but such an approach is usually very costly in terms of additional mask layers and process complexity.

However, for most circuit designs, any simple p-type of device is usually enough to meet most design needs. In a BiCMOS process, the PMOS-transistor can of course be used. In a bipolar RF-IC process, lateral PNP-transistor can usually be obtained without any further process complexity.

While the active devices of the IC-process are continuously improved, there is a need to match this by improved device isolation. For quarter-micron technology and below, shallow-trench isolation (STI) is widely used to achieve an almost planar surface. Using STI, compared to LOCOS isolation, higher packing density, tighter design rules and lower parasitics, and higher yields for both CMOS and bipolar circuits are achieved, see Nandakumar, A. Chatterjee, S. Sridhar, K. Joyner, M. Rodder, and I. -C. Chen, “Shallow Trench Isolation for advanced ULSI CMOS Technologies”, 1998 IEDM Tech. Dig., p. 133. Although demanding on the etching and refilling process steps, STI offers vast improvement in decreased area needed for isolation between circuit elements. Chemical mechanical planarization (CMP) has been widely used in the process flow to realize STI. To further reduce parasitics and cross talk for sensitive analog radio circuitry, deep trench (DT) isolation is used to replace junction isolation between the devices in bipolar processes, see P. Hunt, and M. P. Cooke “Process HE: a highly advanced trench isolated bipolar technology for analogue and digital applications”, Proc. IEEE CICC 1988, p. 816. DT isolation has also been used in CMOS, see R. D. Rung, H. Momose, Y. Nagakubo, “Deep trench isolated CMOS devices”, 1982 IEDM Tech. Dig., p. 237, even though it is less common. For high-performance RF-IC's, STI and DT can be used simultaneously, see the international patent application published as WO 0120664 (inventors H. Norström, C. Björmander and T. Johansson).

However, when using STI isolation for high-performance RF-IC's, the previously so successful utilization of the already existing structure to obtain a lateral PNP-transistor may not be possible. When the epi for the well of the structure is scaled below 1 μm, in conjunction with STI isolation (which reaches about 0.5 μm down from the surface into the epi), no well region is present under the STI isolation on field areas after processing. Instead, the subcollector is found directly under the field oxide. Although it is still possible to find the lateral PNP structure, the base now consists mainly of the heavily doped subcollector region, and consequently the current gain (beta) will be too low to be useful. Another way to obtain a p-type device having reasonable characteristics must be found.

Furthermore, using the STI isolation of today, problems of leakage current between different device areas may arise. Besides, it may be difficult to achieve very low base-collector capacitances in the bipolar transistors and a parasitic pnp-device (extrinsic base/n-well/p-well) of high beta, particularly if the n-well has very low doping, may cause problems.

### SUMMARY OF THE INVENTION

Accordingly, it is an object of the present invention to provide a method in the fabrication of integrated circuits, particularly integrated circuits for radio frequency applications, which provides for effective production of high-quality integrated circuits including bipolar transistors and MOS devices, particularly PMOS-transistors and other p-type MOS devices, by using a minimum of processing steps.

In this respect there is a particular object of the invention to provide such a method, which include a number of multi-purpose processing steps.

To this end, the present invention comprises, according to a first aspect, a method including the steps of:
providing a silicon substrate, which may be a homogenous substrate or an epi layer on top of a wafer;
forming an active region for the bipolar transistor and an active region for the MOS device in the silicon substrate, preferably by doping two surface regions of the substrate and/or two substrate regions of an epi layer on top of the substrate;
forming field isolation areas around, in a horizontal plane, the active regions, preferably by means of shallow trench isolation (STI), and optionally by means of deep trench isolation (DT);
forming a MOS gate stack on the active region for the MOS device, preferably in the form of a gate polysilicon layer on top of a gate oxide layer;
forming a layer of an electrically insulating material, preferably a nitride, on the MOS gate stack and on the active region for the bipolar transistor;
defining a base region in the active region for the bipolar transistor by means of producing an opening in the electrically insulating layer, preferably by means of etching, wherein
the opening in the electrically insulating layer is produced such that the remaining portions of the electrically insulating layer partly covers the active region for the bipolar transistor, i.e. the outer portions along the circumference of the active region; and
the electrically insulating layer remains on the MOS gate region to encapsulate and protect the MOS gate region during subsequent manufacturing steps, including particularly steps of ion implantation, thermal oxidation, and/or etching.

Advantageously, the electrically insulating layer remains also on the collector plug area of the bipolar transistor.

Preferably, a portion of the electrically insulating layer is utilized as a dielectric in a parallel plate capacitor fabricated in the process.

Still a further object of the present invention is to provide a method in the fabrication of an integrated circuit, particularly an integrated circuit for radio frequency applications, for forming a shallow trench for improved isolation of a vertical bipolar transistor comprised in the circuit.

In this respect there is a particular object of the invention to provide such a method, which provides for the fabrication of a bipolar transistor, which does not have current leakage problems.

To this end, the present invention features, according to a second aspect, a method wherein:
a semiconductor substrate of a first doping type, preferably p, is provided;
a buried collector region of a second doping type, preferably n, for the bipolar transistor is formed in the substrate;
a silicon layer is epitaxially grown on top of the substrate;
an active region of the second doping type for the bipolar transistor is formed in the epitaxially grown silicon layer, where the active region is located above the buried collector region;
a shallow trench is formed in the epitaxially grown silicon layer and the silicon substrate, where the shallow trench surrounds, in a horizontal plane, the active region and extends vertically a distance into the substrate; and
the shallow trench is filled with an electrically insulating material.

Preferably, the buried collector region and the shallow trench are formed relative each other such that the buried collector region extends into areas located underneath the shallow trench.

Yet a further object of the present invention is to provide an integrated circuit, particularly an integrated circuit for radio frequency applications, including a vertical bipolar transistor, which is isolated by means of a shallow trench in a novel manner, such that an improved performance of the transistor, and thereby the integrated circuit, can be achieved.

To this end, the present invention includes, according to a third aspect, an integrated circuit comprising:
a semiconductor substrate of a first doping type, preferably p, where the substrate has an upper surface;
a vertical bipolar transistor formed in the substrate, where the transistor includes an active region of a second doping type, preferably n, where an emitter and a base are formed, and a buried collector region of the second doping type, where the buried collector region is located underneath the active region;
a shallow trench for isolation of the vertical bipolar transistor, where
the shallow trench surrounds, as seen along the surface of the substrate, the active region of the transistor, is filled with an electrically insulating material, and extends vertically from the upper surface of the substrate and down into the substrate to a depth where the buried collector region is located.

The buried collector region extends preferably into areas located underneath the shallow trench, and the buried collector is connected to a collector plug, which also is surrounded by shallow trench.

### BRIEF DESCRIPTION OF THE DRAWINGS

Further characteristics of the invention and advantages thereof will be evident from the detailed description of preferred embodiments of the present invention given hereinafter and the accompanying FIGS. 1-22, which are given by way of illustration only, and thus are not limitative of the present invention.

FIGS. 1-3, 4a, 5-19, and 20a-b are highly enlarged cross-sectional views of a portion of a semiconductor structure during processing according to a preferred embodiment of the present invention.

FIGS. 4b and 20c are SIMS (secondary ion mass spectroscopy) diagrams showing doping profiles of an n-well on top of a buried collector structure and of an NPN transistor, respectively, as fabricated according to the preferred embodiment of the present invention.

FIG. 20d is a diagram of the base-collector capacitance as a function of base-collector bias voltage for NPN transistors produced according to a production process of the invention (lower curve) and according to a prior art production process (upper curve)

FIGS. 21-22 illustrate the layout of the most important masks and the electrical connections to component areas of the main components as manufactured according to the present invention.

### DETAILED DESCRIPTION OF EMBODIMENTS

In the following description, for purposes of explanation and not limitation, specific details are set forth in order to provide a thorough understanding of the present invention. However, it will be apparent to one skilled in the art that the present invention may be practiced in other versions that depart from these specific details.

This description describes a manufacturing method for an integrated silicon bipolar circuit for high frequency applications, including NPN-transistors, nitride and MIM (metal-insulator-metal) capacitors, and resistors. Particularly, the present description illustrates the concept of integrating PMOS transistors into the circuit with the purpose of creating simple p-type of devices, which are necessary for circuit design.

The importance of selecting a depth of the STI, such that the isolation reaches down to a highly doped subcollector layer, is emphasized.

Available devices are the following ones:
NPN
PMOS
Quasi-lateral PNP device (derived from PMOS)
Nitride capacitor
MIM capacitor
Polysilicon resistors

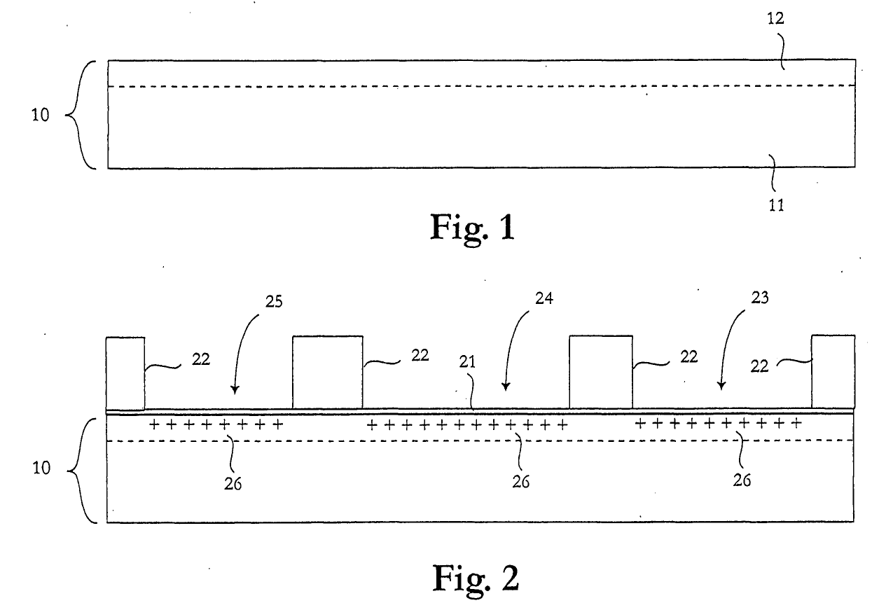

With reference now to FIGS. 1-22 a detailed description of an inventive embodiment of the process flow for manufacturing high-performance NPN-transistors, PMOS-transistors and passive elements is presented in detail in twenty-two numbered sections.

1. Starting Material

FIG. 1 shows a cross section of a silicon p-type wafer, boron doped, before formation of a buried n+ layer (subcollector). The silicon wafer is an epi-wafer, including a substrate 10 consisting of a highly doped p+ wafer 11 having typically a resistivity of 10 mOhmcm, on which a low-doped silicon layer 12 of p-type has been grown. This epi layer is typically 5-10 μm thick and has typically a resistivity of 10-20 Ohmcm.

It shall be appreciated that in a preferred version of the invention the low-doped silicon layer 12 of p-type is much thicker than illustrated in FIG. 1.

Alternatively, the p-type wafer can be a homogeneously low-doped p-type wafer (not illustrated) having typically a resistivity of 1-20 Ohmcm.

Note that the term substrate in the summary above as well as in the description and the claims may refer to a homogeneous silicon substrate or to a structure with an epitaxial layer on top of a wafer.

2. Subcollector Implantation

With reference next to FIG. 2 a thin protective layer 21 of silicon dioxide is formed on the surface of the silicon substrate 10 by thermal oxidation, to a thickness of typically 20 nm. The purpose of this layer is to serve as a protective screen against contamination by metals or other impurities during the implant. The layer thickness is selected such that ion implantation in a following step can be performed through the layer 21.

A film 22 of photoresist is applied on the wafer surface and patterned by photolithography. The purpose of this patterned layer, also called SUB mask, is to define an area 23 for a buried collector of a bipolar transistor and doped buried areas for a PMOS transistor 24, and for a capacitor 25, respectively, by masking subsequent ion implantation.

Next, ions for the doping of the subcollector are implanted, preferably arsenic using an energy of about 50 keV and dose of about 6E 15 cm⁻², the doped areas being denoted by 26 in FIG. 2. (Throughout the description the annotation XXEYY will be used instead of XX * 10^{YY}.) The energy has been selected such that the ions reach into the silicon through the thin oxide layer on unprotected areas, but is hindered to penetrate the silicon on areas protected by photo resist. After implantation, the photo resist is removed by common wet or dry chemical methods.

Other n-type dopants may alternatively be used to form the n+ subcollector region, e.g. antimony (Sb). However, using arsenic a lower resistivity for a given layer thickness can be obtained, which is advantageous for the devices, e.g. lower collector resistance and lower sidewall collector-substrate capacitance. Also, since the diffusitivity of arsenic is higher than Sb, a shorter drive-in time and lower temperature is necessary to obtain a desired subcollector profile.

3. Subcollector Drive-in and Oxidation and P-type Isolation Implant

Next, a three-step heat treatment is made.

First a 600° C. anneal is used to recrystallize the damage in the implanted area.

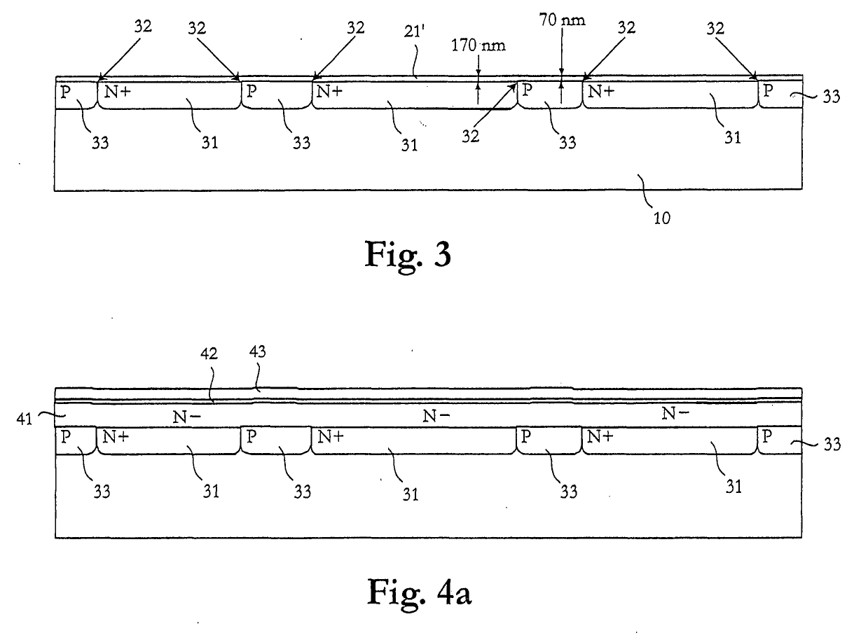

Next, a high temperature drive-in at about 1100° C. is performed to redistribute the arsenic implanted in the subcollector, such that doped regions 31 as shown in FIG. 3 are obtained.

The temperature is then lowered to about 900° C., where an oxidation is done in a wet atmosphere. Since highly doped n-type areas have a higher oxidation rate, on the areas implanted with arsenic a thicker oxide (˜170 nm) will be obtained here than on the non-implanted areas (˜70 nm). Since silicon atoms will be consumed during this oxidation 40-50 nm high steps 32 will remain in the silicon surface after removal of the oxide. The imprint will later serve as an alignment mark at a subsequent lithography step.

Conventionally, a one-temperature oxidation in the range of 1100° C. is used for this step. To create sufficiently high steps, a thicker initial oxide has than to be grown prior to arsenic implantation. The oxide is patterned and etched to define buried collector regions, whereupon a thin screen oxide is grown in etched openings prior to implantation. The major contribution to the alignment step in the silicon comes from different oxide growth rates of thin and thick oxide regions. By using the lower oxidation temperature, as described in Y. -B. Wang, P. Jönsson, and J. V. Grahn, “Arsenic Enhanced Oxidation and Effective Control of Buried Collector Step”, 196th Meeting of The Electrochemical Society (Honolulu, Hawaii, Oct. 17-22, 1999), a simplified process flow without the need of separate layers for creating alignment marks can be used.

Before removing the oxide, a p-type ion implantation, consisting of boron at a typical energy of about 120 keV and dose of 8E12 cm⁻² is performed, the resulting p-doped regions being indicated by 33 in FIG. 3. The implantation is performed without any mask. The energy and dose is selected such that, in the n+ subcollector arsenic doped areas 31, the implanted boron is substantially not affecting the doping level (the number of donor atoms will essentially be unchanged). In the areas between the subcollector areas, however, moderately doped p regions 33 are formed, which will isolate the n regions 31 from each other.

It shall be pointed out that it is possible to dispense with the aforementioned p-type implantation and yet obtain functional devices by increasing the initial doping level of the starting material, from lowly p-type to moderately p-type. However, the collector-to-substrate capacitance, from the n+ subcollector region down to the p- substrate, will in such case be higher.

The general procedure how to make subcollector n+ regions and in-between p-regions is also shown in U.S. Pat. No. 5,374,845 to Havemann. This patent, however, refers to Sb-doped layers, and the alignment step is created in a conventional way using a nitride-oxide bi-layer.

4. Epi Deposition and N-well Implantation

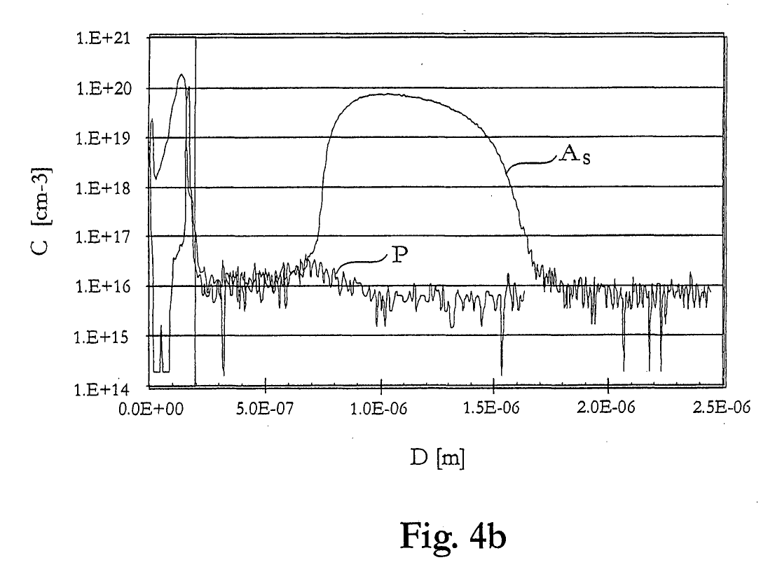

The oxide 21 is removed, preferably by wet chemistry (hydrofluoric acid, HF). The previously described steps 32 at the silicon surface will appear, and an undoped (intrinsic) epitaxial silicon layer 41, having a thickness of about 0.5 to 1 μm is grown on the surface using common techniques, see FIG. 4a. The layer 41 may alternatively be n-type doped during the epitaxial growth. A typical doping level would be about 1E16 cm⁻³. In the U.S. Pat. No. 5,374,845 to Havemann, the corresponding epitaxial layer is lightly doped (a resistivity higher than 10 Ohmcm), but is still considered to be essentially intrinsic. However, a homogeneously doped n-type epitaxial layer will later in the process flow complicate the formation of substrate surface contacts, so-called top-down contacts.

During the epitaxial growth, high temperatures, in the 1100° C. range, are used. Acceptor atoms in the p-type implanted regions 33 will diffuse into the substrate, such that buried p- regions will be formed beneath the epitaxial silicon 41 in areas where no n+ subcollectors 31 are present. Note that the previously described step is reproduced at the top surface of the epitaxial silicon layer.

The epitaxial layer will, as described below, be doped in selected region to obtain regions of n- and p-type (n-wells and p-wells). In the n-type regions, placed directly above n+ subcollectors 31, bipolar transistors and capacitors are formed. Substrate contacts from the surface down to the substrate are formed in p-type regions between n-type regions.

To obtain an NPN transistor with good linearity (i.e. adds little distortion when amplifying a signal), low base-collector capacitance with small voltage-variation is advantageous. The thickness of the epi and the doping of the n-well shall be selected in the present invention so that when used in the NPN transistor, the n-well will fully deplete, from the base to the subcollector, already at low base-collector bias voltage. The base-collector capacitance will therefore show almost constant value for a wide bias range. This behavior is similar to a “punch-through” collector device, see Niu et al., Proceedings of the IEEE BCTM Conference 1999, p. 50-53.

The formation of a hard mask for a shallow trench is next made. The masking layer for the shallow trench is formed by oxidizing the silicon surface to form a layer 42 of thermal silicon dioxide typically of a thickness of about 10 nm. Next, an approximately 200 nm thick silicon nitride layer 43 is deposited by chemical vapor deposition (CVD). Other combinations of thicknesses and/or masking materials are possible.

An ion implantation through the hard mask follows which forms the aforementioned n-wells in the epitaxial layer. For this n-type implantation, phosphorous is preferably used, typically at an energy of 650 keV and a dose of 9E11 cm⁻². The implantation is performed without any lithographic mask layer. Depending on the electrical requirements and the thickness of the n-well, the energy and dose can be selected in a wide range. The ion implantation may alternatively include a multiple of implantations at different energies and doses, to obtain a smoother profile or a doping profile that is highly doped away from the surface, i.e. a so-called retrograde profile. The whole surface region of the wafer consists now of n-well. P-wells in selected areas will be formed at a later stage, see section 9 below. The n-well profile can alternatively be formed by in-situ doping of the epi-layer with e.g. phosphorous or arsenic.

The resulting structure is shown in FIG. 4a and the doping profile of the n-well on top of the buried collector structure at this stage is illustrated by the SIMS diagram in FIG. 4b.

In sections 5-8, the device isolation using shallow and deep trench isolation will be described. The isolation scheme is also described in the international publication WO 0120664.

5. Formation of Shallow Trench and Active Areas

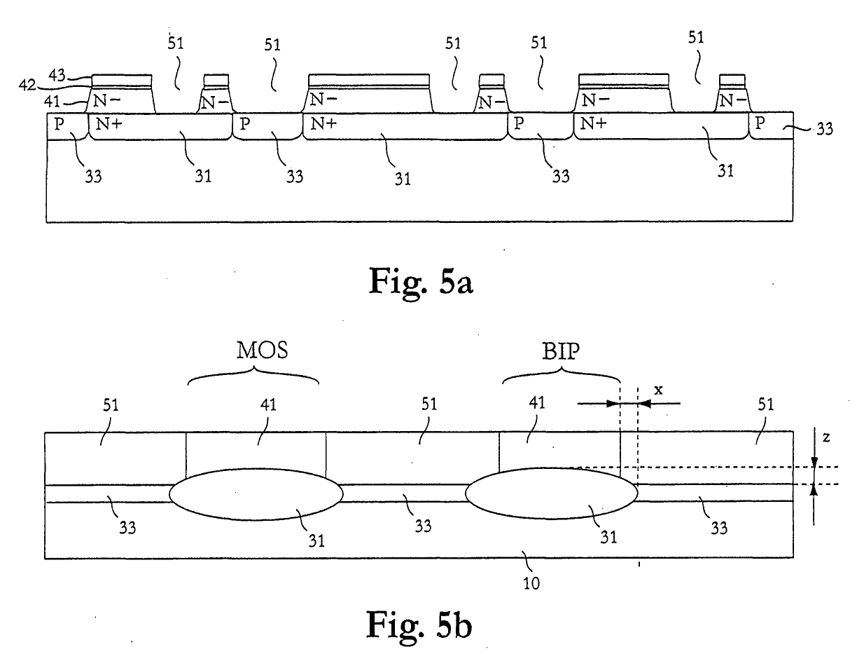

The formation of a shallow trench is now considered. A photo resist (not illustrated) is applied on the nitride layer 43, and is exposed using a first mask, so called STI mask, which leaves openings were the shallow trench is to be etched. The etching, which preferably is anisotropic, is performed by reactive ion etching (RIE), through the nitride/oxide layers and into the silicon substrate to form tapered (vertical) shallow trenches 51 as shown in FIG. 5a. The preferred depth of the trenches is 0.2-0.7 μm, or more typically 0.3-0.5 μm, from the upper surface of silicon layer 41.

The photo resist is removed subsequent to the etching of the shallow trenches.

Alternatively, oxide/nitride bi-layer 42, 43 is etched, after which the resist is stripped. Then, in a step the STI is etched using the bi-layer 42, 43 as a hard mask.

An alternative preferable design of the shallow trenches 51 will be described briefly with reference to FIG. 5b.

The shallow trenches 51 can be formed such that they extend vertically from the silicon surface, i.e. surface of silicon layer 41 on top of substrate 10, and down to the buried collector region 31, and preferably further down to a depth which is deeper than the depth of the buried collector layer 31; the overlap distance being denoted by z in FIG. 5b.

Further, the buried collector region 31 and the shallow trench 51 can be formed relative each other such that the buried collector region 31 extends into areas located underneath said shallow trench, such areas being denoted by x in FIG. 5b.

Such design exhibits a number of advantages. Problems of a leakage current between different device areas are avoided; and thus an improved device isolation is obtained.

The design provides for a lowly doped n-well 41 (especially suited for the bipolar transistors) due to the deeper shallow trench. Low values of the base-collector capacitance C_{bc} can be realized. A parasitic p/n/p device, which may result from other processes, consisting of extrinsic base/n-well/p-well, is avoided, since buried collector areas also extend under the shallow trench corners (to a distance x as illustrated in FIG. 5b). In a junction-isolated process, this parasitic device may have a beta larger than 10. A lowering of the n-well doping would increase beta as well as the risk of punch-through of the structure if not this inventive shallow trench structure is used.

By the use of such inventive STI isolation, deep trench isolation, to be discussed in the following two sections, may be dispensed with, and still obtaining an isolation free from latch-up problems.

6. Formation of Hard Mask for Deep Trench, and Deep Trench Etching

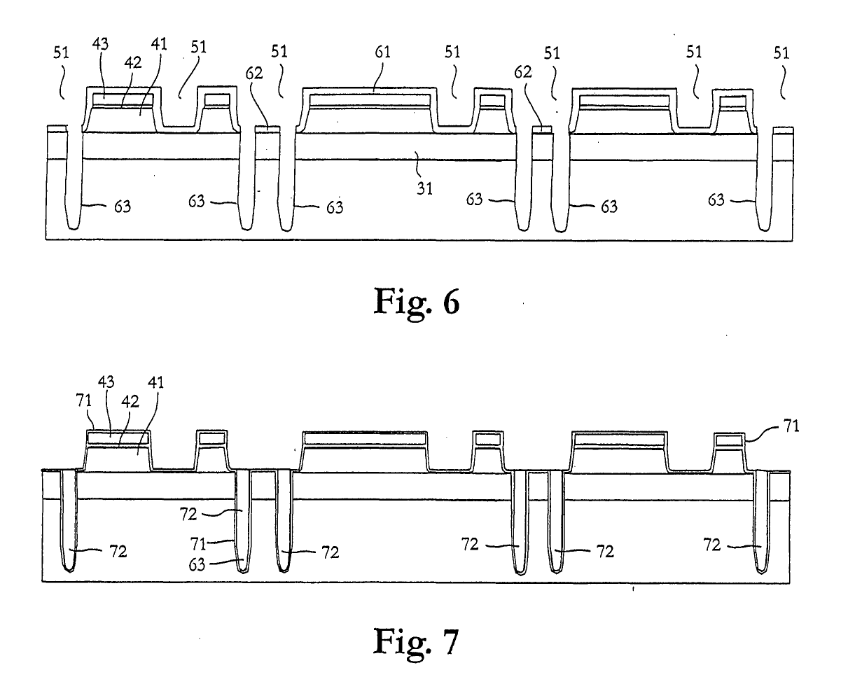

With reference to FIG. 6 the formation of a hard mask for a deep trench is described. A silicon dioxide layer 61, typically of thickness 0.1-0.5 μm, is deposited, preferably conformably, e.g. by CVD, on top of the structure (i.e. remaining portions of the nitride layer and in the shallow trench). It is preferred that the oxide layer is deposited conformably as otherwise margins for subsequent masking and etching will be reduced. Photo resist is applied, and is exposed using a second mask, so called deep trench mask (not illustrated). The opening(s) of the trench mask may be placed anywhere inside the shallow trench regions. The width of the deep trench can be chosen by using different mask dimensions. It is usually preferred to use trenches of fixed lateral dimensions (thicknesses), preferably of about 1 μm or less, as problems otherwise will occur using a non-uniform etch and difficulties to refill and planarize the deep trench.

The oxide layer is etched by reactive-ion etching (RIE) to define the trench openings extending to the bottom surface of the shallow trench. On top of the nitride layer, the oxide layer is protected by the photo resist mask, and this oxide will later serve as a hard mask for these areas during the following etch step. The oxide layer is retained at portions 62 of the shallow trench area, where no deep trenches will be formed. After etching the photo resist is removed.

In the international publication WO 0120664 mentioned above is discussed how to select the deposited silicon dioxide layer and align the trench mask such that the deep trench will be self-aligned to the edge of the shallow trench.

Then, deep trenches 63 are formed by etching, using the oxide 61 as a hard mask. If an oxide spacer is created, it defines the distance from deep trench to the active area. The depth of the deep trenches is at least a few microns, and more preferably at least 5 microns. The resulting structure is shown in FIG. 6. The trench profile can be made straight, and/or tapered, with bottom roundings.

Note that in the preferred version of the invention with thick low-doped silicon layer 12 of p-type referred to in section 1 above, the low-doped silicon layer 12 may reach down to a depth essentially corresponding to the positions of the reference numerals 63 in FIG. 6.

The oxide hard mask for the patterning of the deep trenches is subsequently removed in e.g. HF.

7. Filling and Planarization of Deep Trench

Subsequent filling and planarization of trench areas 51, 63 can be accomplished in several manners known in the art. As an illustrative example, the processing is continued by performing a liner oxidation, which purpose is to perform corner rounding at the sharp edge of the trenches, to reduce stress and unwanted electrical effects. This is accomplished by growing a thin (20-30 nm) thermal oxide 71 at high temperature (>1000° C.), see FIG. 7. The trench is filled in a conventional manner with a 200 nm thick layer of TEOS and with 1500 nm of polysilicon 72. The polysilicon is then etched back to remove all polysilicon from the shallow trench areas.

Alternatively, the polysilicon is planarized by chemical mechanical polishing before the polysilicon is etched back in the shallow trench areas. Hereby, the recess of the polysilicon fill in the deep trench is reduced, and consequently, a thinner oxide can be deposited in the subsequent step to fill the shallow trench

The resulting structure is shown in FIG. 7.

8. Filling and Planarization of Shallow Trench, Bi-layer Strip

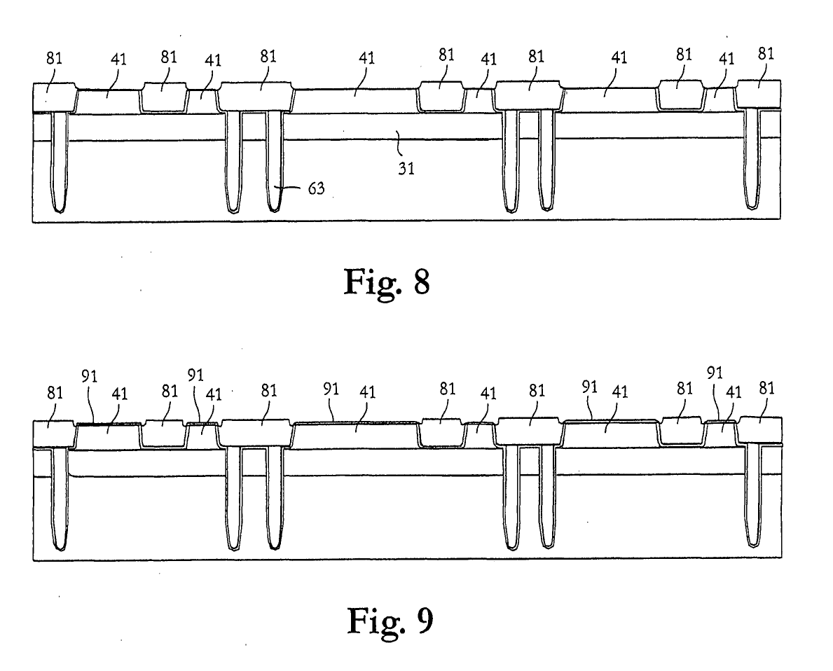

Next, the remaining shallow trench is filled with e.g. CVD oxide or a high density plasma (HDP) oxide 81, and planarized, either by dry etching methods or by chemical mechanical polishing, see FIG. 8.

As finishing steps for this process module, the nitride 43 and the oxide 42 (seen inter alia in FIG. 7) on the device areas are removed, preferably by wet methods. The remaining structure now consists of oxide 81 on isolation areas, and bare silicon 41 on device areas.

9. Formation of P-wells

In selected areas (not illustrated in the Figures), p-wells will next be formed. In a BiCMOS process, the p-wells are mainly used for NMOS-transistors and p-type substrate contacts. In a pure bipolar process, the p-well areas are mainly used for substrate contacts. Later in the process flow, a highly doped p+ contact at the surface can be formed. The p-well areas are designed such that there will be no subcollector n+ areas under the p-well areas, and thus the p-well areas can directly contact the p-type substrate.

The p-wells are formed by first growing a protective oxide 91, see FIG. 9. The oxide 91 will later in the process flow also serve as pad oxide between the silicon substrate and deposited silicon nitride. The thickness of the oxide 91 is typically 10 nm.

A photo mask (not illustrated), called p-well mask, is then deposited and patterned. Boron is ion implanted in the silicon. The energy and doses are selected such that the ions penetrate through the oxide into the silicon, but not through the photo mask. A double implant may be used to obtain a smoother or retrograde doping profile. In a particular example, a double implant of boron at an energy of 100 keV and a dose of 8E12 cm⁻², together with another implant at an energy of 200 keV and a dose of 1E13 cm⁻² were used to obtain a p-well doping about 1E16 cm⁻³ in the selected areas. After implantation, the photo mask is removed using conventional wet or dry methods.

In sections 10-12, additional steps for creating a PMOS-device in the process flow will be described. The reason for adding the PMOS device to the RF-IC process flow was discussed previously in the text. The additional steps, as they are described here, can be completely omitted without affecting any other devices on the wafer.

The aspects of the integration of a simple PMOS transistor with n+ gate and a lithographical gate length of about 0.8 μm will now be discussed, see e.g. pp. 392-397 in S. Wolf, “Silicon Processing for the VLSI Era, Volume 2—Process Integration”, Lattice Press, Sunset Beach, 1990. In conventional CMOS/BiCMOS processes in the 0.5-2 μm gate length range, the most common choice for the gate material is heavily doped n-type polysilicon. In a double-poly bipolar process, heavily doped n+ and p+ polysilicon are both available. An n+ gate PMOS transistor was selected due to process integration issues. The work function of the n+ gate polysilicon is ideally suited for the n-device, and for the p-device, a buried channel device will form. To adjust the threshold voltage to the desired −0.5 to −1 V range, a p-type implantation (boron) is used. This overcompensates the n-surface such that a p-region depleted of holes is formed. The exact boron dose is dependent on several parameters, e.g. gate oxide thickness and well doping.

10. Adding a PMOS Device: Threshold Voltage Adjustment

At this stage, the wafer surface consists of field oxide regions with thick oxide 81 (the STI), and device areas with thin oxide 91 (the 10 nm p-well oxide) as illustrated in FIG. 9.

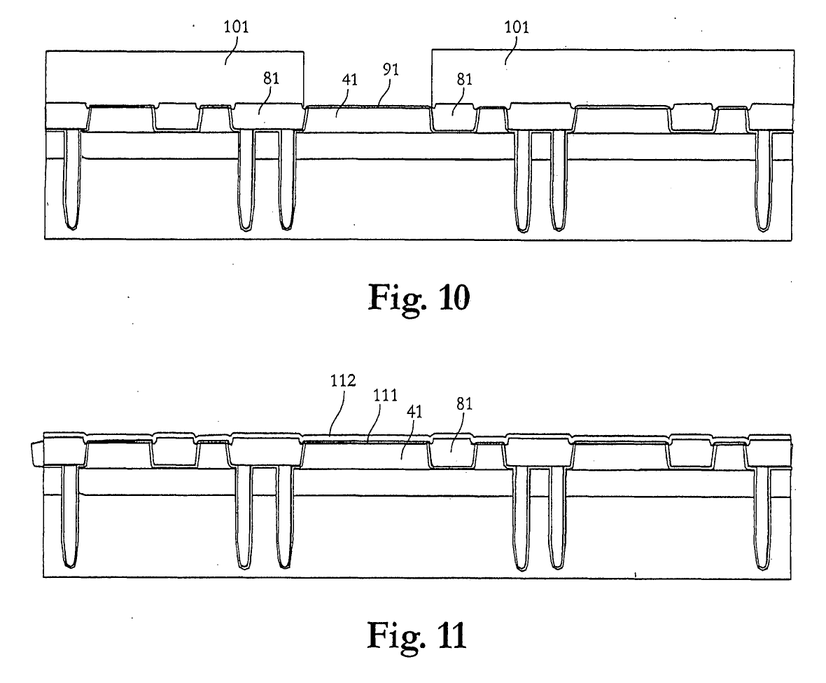

A photo mask 101 is now applied, see FIG. 10, which is open on the areas, which shall serve as device areas of the PMOS device. The wafer is then implanted with a p-type dopant, boron. The energy is selected such that the dopant penetrates the areas not covered by the photo mask, but which are covered by thin oxide. Typically, an energy of 20-50 keV is used. The dose is selected to adjust the threshold voltage (VTP) such that it will be in the −0.5 to −1 V range. A typical dose of 1E12-1E13 cm⁻² is used. The exact dose, or combination of doses and elements, is dependent on the oxide thickness and the background doping of the substrate under the PMOS gate, which in this process flow is set by implantations described in sections 4 and 17, i.e. n-well implant and secondary collector implant.

Subsequently, the photo mask 101 is removed.

11. Adding a PMOS Device: Gate Oxide and First Gate Material Formation

The p-well oxide (also known as Kooi-oxide 91 in FIGS. 9-10) is removed by wet etching in HF, and is replaced by a gate oxide 111 for the PMOS transistor using thermal oxidation see FIG. 11. This oxide renewal is due to high MOS requirements, as the quality of the p-well oxide is normally not sufficient as it has withstood several ion implantations.

Typically, a thickness of 15 nm or less will be selected for the gate oxide 111 thickness. In this particular example, which should support 5 V operation, a thickness of 12 nm is used.

Following directly, a first undoped silicon layer 112 is deposited, using LPCVD, on the gate oxide 111. The deposition parameters are selected such that a non-crystalline layer is formed (alpha-silicon). This is achieved when the deposition temperature is below about 550° C. The thickness of this layer is quite thin, typically in the 100 nm range, preferably 70 nm. Poly-silicon, which is formed at deposition temperature of about 625° C. can alternatively be used to protect the gate oxide. Using a polysilicon material, a wet etchant may penetrate the grain boundaries, but if an almost homogeneous alpha-silicon material is used instead, this effect is greatly reduced.

The resulting structure is shown in FIG. 11.

If the process integration so requires, a thin oxide layer (not illustrated) may be formed on top of the poly silicon at this stage. The thin oxide may consist of thermally grown oxide, deposited oxide, or thick natural oxide.

12. Adding a PMOS Device: MOSBLK-etch

The deposited silicon layer 112 needed to form part of the PMOS gate must now be removed from the other areas of the wafer.

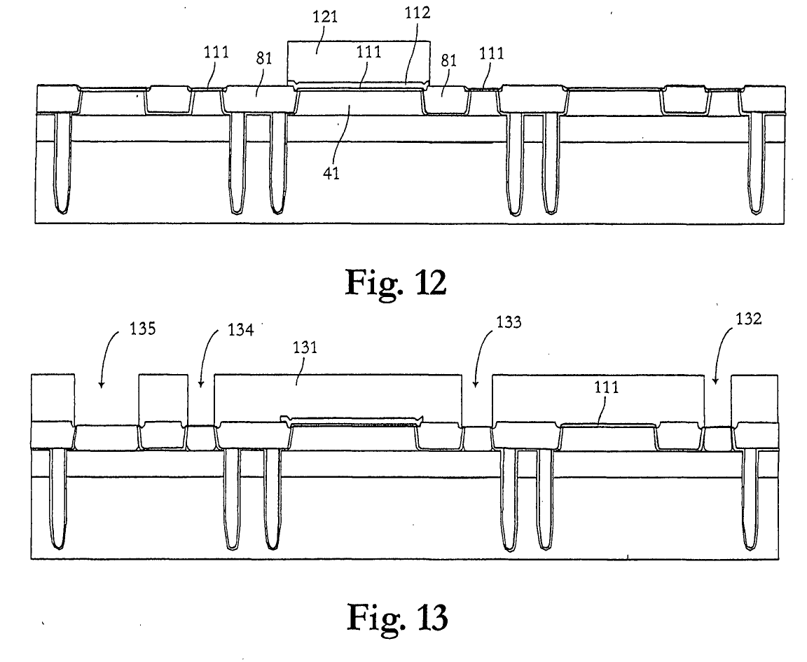

A photo mask 121, which covers the PMOS device areas (MOSBLK mask, a reversed mask version of PMOS/VTP-mask 101) is applied to the wafer, see FIG. 12. Using mask 121 silicon is removed by dry etching, using the field oxide/gate oxide 81/111 as etch stop. The resulting structure is shown in FIG. 12.

The photo mask is then removed using conventional methods.

13. Collector Contact

For the formation of active devices (e.g. a transistor), a low-resistance path, from the surface of the wafer to the subcollector (e.g. a collector plug) is needed. Also, other kind of such low-resistance paths may be needed. Such paths are defined lithographically, by depositing and patterning of photoresist to obtain a DNCAP mask 131, such that open areas 132, 133, 134, 135 are created where the paths such as collector plugs are to be formed, see FIG. 13. In the illustrated circuit example, open area 134 is located where a plug together with a subcollector will form one electrode in a parallel plate capacitor. Consequently, the photo mask also defines capacitor area 135.

After the photoresist layer has been patterned, doping is made in the open areas. This is preferably performed using ion implantation, e.g. phosphorous at an energy of 50 keV and dose of 5E15 cm⁻², but other dopants, such as arsenic, can alternatively be used, either solely or in combination with phosphorous. Particular care must be exercised when trench isolation is adopted. The details of the selection of energy and doses are discussed in international patent application published as WO 9853489 (inventors: H. Norström, A. Lindgren, T. Larsson, and S. -H. Hong).

After the implantation, still having the photo mask 131 present on the wafer, the thin protective silicon dioxide layer 111 is removed in the open areas, preferably using dry etching. Note that the oxide layer 111 is still present in other areas still covered by photoresist, e.g. parts of the device areas where the base region of the bipolar NPN-transistor later will be formed (between the areas denoted 132 and 133).

The resulting structure is shown in FIG. 13.

The photoresist is then removed by conventional methods, after which the silicon wafer is given a two-step heat treatment, typically at 600° C. for 30 minutes, followed by treatment at 900° C. for 30 minutes in non-oxidizing atmosphere, e.g. containing N₂ or Ar. When using a thin epi, such in the present process flow, the heat treatment may be omitted without increase of collector resistance.

14. Nitride Capacitor Formation and Formation of Emitter/base Openings

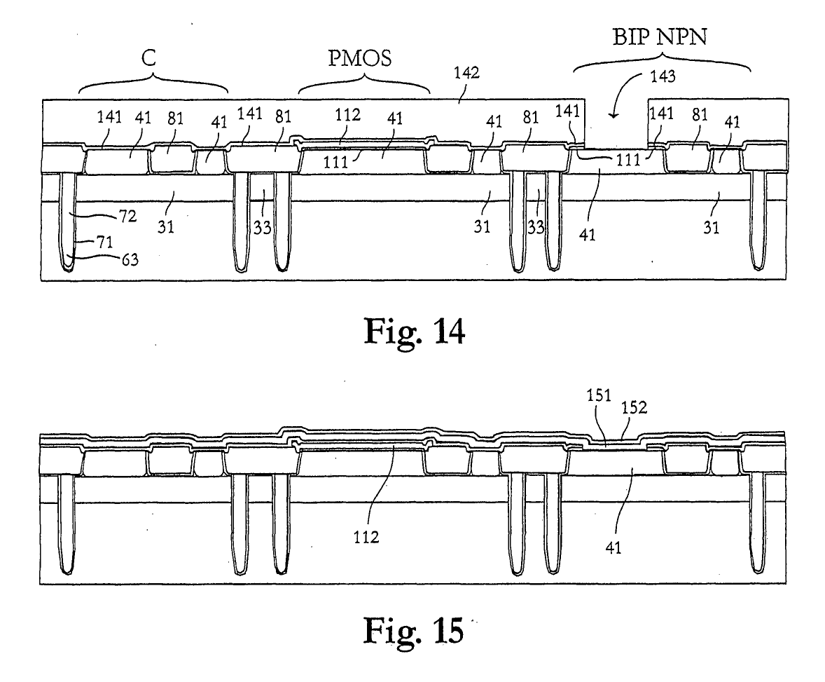

After the heat treatment, a thin silicon nitride layer, denoted 141 in FIG. 14, is deposited, preferably using LPCVD-technology and typically to a thickness in the range of 20 nm. The purpose of this layer is threefold:
(i) The portion of the nitride layer in direct contact with the silicon wafer in the capacitor area will serve as dielectric in the capacitor to be formed. Since the silicon nitride has a dielectric constant (eᵣ), which is approximately two times higher the than dielectric constant of silicon dioxide, a higher capacitance per area unit is obtained using nitride instead of oxide.
(ii) The portion of the nitride layer that is deposited on the oxide in the active area, where the base connection is to be formed, gives an additional thickness to this insulating dielectric layer, which results in lower parasitic capacitance for the base-collector junction.
(iii) A portion of the nitride layer encapsulates the first gate material 112 of the PMOS transistor during subsequent processing.

The nitride serves the purpose of an oxidation-resistant mask. In absence of a protective nitride film, the heavily doped collector plug would oxidize heavily, which eventually would cause generation of defects. It is therefore essential that the nitride layer remains on the collector plug area. Moreover, the nitride also protects the first polysilicon layer in the MOS gate stack from unwanted oxidation.

Prior to depositing the silicon nitride layer, the wafer may be cleaned shortly in diluted HF to remove any silicon dioxide possibly formed on the highly doped n+ areas.

A different concept for realizing a reduced emitter-base capacitance for a single-poly bipolar transistor in a BiCMOS flow is described in the following patents: U.S. Pat. No. 5,171,702 to S. H. Prengle and R. H. Eklund, and the previously mentioned U.S. Pat. No. 5,374,845 to R. H. Havemann.

Subsequent to the deposition of nitride layer 141, the wafer is lithographically patterned by depositing a photoresist layer 142 and then opening the resist for the NPN-transistor to be formed, a so called E/B mask, as well as for any substrate contacts in p-type areas (not illustrated). Opening 143 for the NPN-transistor is placed in an area with no field oxide 81 under the nitride 141, and properly spaced from the field oxide edge. Openings for substrate contacts are placed in p-well regions, on top of buried p-type regions (not illustrated).

The nitride 141 and oxide 111 layers in the openings are removed by conventional etching, preferably by dry methods, and preferably in a procedure where the nitride and oxide are sequentially etched. The etching is finished when the surface of the silicon layer 41 is exposed. For the NPN-transistor, the described method reduces the base area to the area set by the pattern, instead of the larger area defined by the field oxide openings. In this manner the base of the NPN-transistor can be separated from the edges of the field oxide areas, where a higher stress may exist. Such method of creating a well-defined smaller opening reduces the collector-base capacitance.

The resulting structure is shown in FIG. 14.

Subsequent to the etching of the nitride 141 and the oxide 111 down to the silicon layer 41, the photo mask 142 is removed by conventional methods.

15. Formation of Extrinsic Base Layer

A thin silicon layer 151, in the range of 200 nm, is next deposited on the structure using CVD-technique, see FIG. 15. The deposition conditions are selected such that the layer 151 will be amorphous, but microcrystalline or polycrystalline silicon can alternatively be used. The purpose of the layer is to serve as an extrinsic base contact for the NPN-transistor, and the top electrode of the nitride capacitor.

After this deposition, an ion implantation is performed. The purpose is to heavily dope the amorphous silicon layer to p-type. The selected species for ion implantation is preferably BF₂ at an energy of about 50 keV and a dose of about 2E15 cm⁻². Boron is alternatively implanted at lower energy. The energy is selected such that the implanted boron atoms will not reach through the deposited silicon layer 151. If a non-crystalline silicon layer is employed the control of the implanted doping profile is enhanced.

On top of the silicon layer 151, a silicon dioxide layer 152 of a typical thickness of 150 nm is deposited using PECVD technique. Other types of low-temperature oxide, e.g. LTO, can alternatively be used. The purpose of using the PECVD technique is to keep the temperature so low that the amorphous silicon will not re-crystallize during the oxide deposition. The advantages of having an amorphous silicon layer implanted with BF₂ beneath a layer of silicon dioxide deposited by PECVD during the formation of extrinsic base contacts for NPN-transistor is further described in the U.S. Pat. No. 6,077,752 to H. Norström.

The resulting structure is shown in FIG. 15.

16. Patterning of Emitter Openings

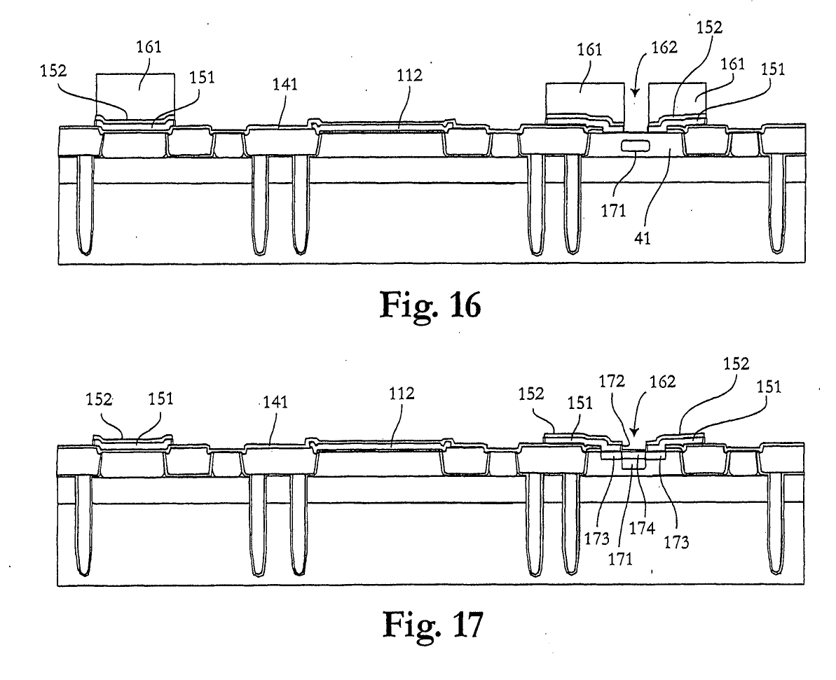

Next, a photo mask 161, called RFEMIT mask, is applied to the structure, see FIG. 16. The resist protects the upper electrode of the nitride capacitor, p-type substrate contacts and the areas, which will form extrinsic base areas of the NPN-transistor. Using the photoresist as a mask, the silicon dioxide 152 and the amorphous silicon 151 deposited in the previous step, is now removed using dry etching. The etching is stopped when the silicon nitride layer 141 is completely exposed on open field areas where it protects the collector areas and MOS devices.

The etch is advantageously performed in a multi-chamber system (cluster system). In this case, an overetch removing 20 nm of silicon is performed in area 162 with exposed silicon, i.e. the later defined intrinsic base area of the NPN-transistor. On top of the PMOS transistor, the similar silicon nitride 141 is present, and the etching will stop on this nitride and leave the nitride almost intact.

The resulting structure is shown in FIG. 16.

17. Selective Implanted Collector

Next step is an additional doping in what will become the collector of the NPN-transistor, a so-called secondary implanted collector (SIC), indicated at 171 in FIGS. 16 and 17. The purpose is to minimize base widening and thereby improve the high-frequency properties of the transistor. In this particular case, it is performed as a double phosphorous implantation. During the first step, 5E12 cm⁻² of phosphorous at an energy of 200 keV is implanted, and during the second step, 4E12 cm⁻² phosphorous at an energy of 420 keV is implanted. The order of these steps may be reversed, and the exact energy and dose may have to adjusted to fit actual process parameters, such as epi thickness, temperature drive etc. during the processing.

Note that since the photoresist 161 from step 16 protects part of the NPN transistor such that the implantation is only performed into the emitter-base opening, and as a consequence of thereof, no increased collector doping is obtained under extrinsic base contact 151. Hereby a low collector-base capacitance of the NPN-transistor is preserved.

The PMOS transistor is not covered by any photo mask during the implantation and is totally penetrated by the implanted species, which sets the background doping of the n-well for the PMOS transistor. The implant parameters will therefore affect the threshold voltage of the transistor, but can be compensated for by changing the threshold voltage implantation dose made in step 11.

After the implantation, the resist is removed using conventional methods, and a thin silicon dioxide 172, in the range of 10-20 nm, is thermally grown on the wafer surface where bare silicon is exposed, that is, in the intrinsic base opening 162 (FIG. 17). The growth is made in wet atmosphere at the comparatively low temperature of 800° C. During this step, the remaining PECVD-deposited oxide layer 152 on top of the extrinsic base electrode 151 will consequently densify. On the sidewall of the structure, thermal oxide will grow on the exposed silicon. During the heat treatment, the amorphous silicon 151 is converted to poly crystalline silicon, at the same time as the previously implanted boron is redistributed within the polysilicon to form p-type base contact paths 173.

18. Intrinsic Base Formation

In next step, boron will be implanted into the structure to form the intrinsic base region 174 of the NPN-transistor. In this particular examples, a boron dose of about 1.5E14 cm⁻² is implanted at an energy of about 6 keV. Changing the thickness of the thin oxide formed in the previous step may require change of the implant parameters. The implantation only penetrates into the silicon in the base area, as other silicon areas are protected by means of nitride layer 141.

After the implantation, the structure is further oxidized, preferably in wet atmosphere at 800° C., which reduces the concentration of boron atoms at the silicon/silicon dioxide surface.

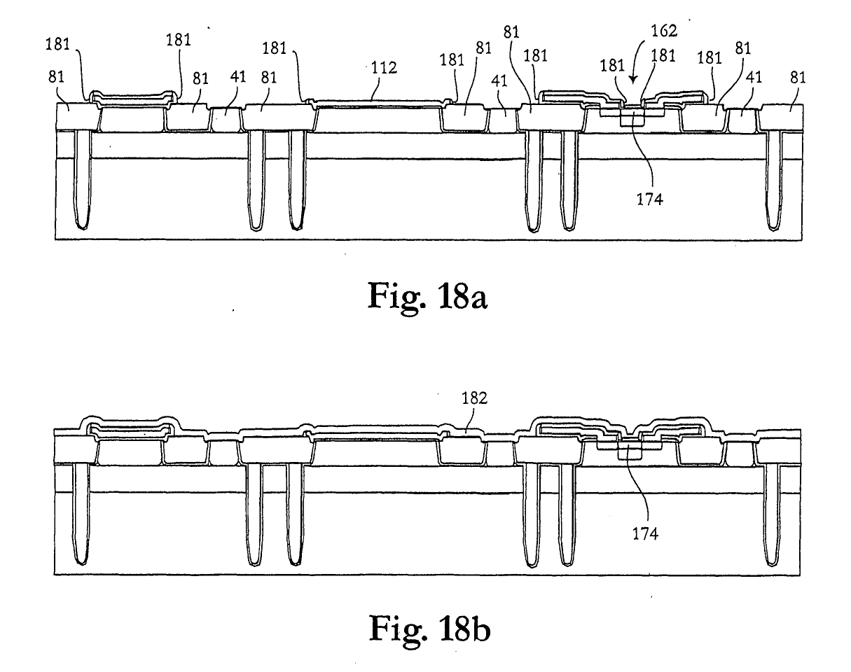

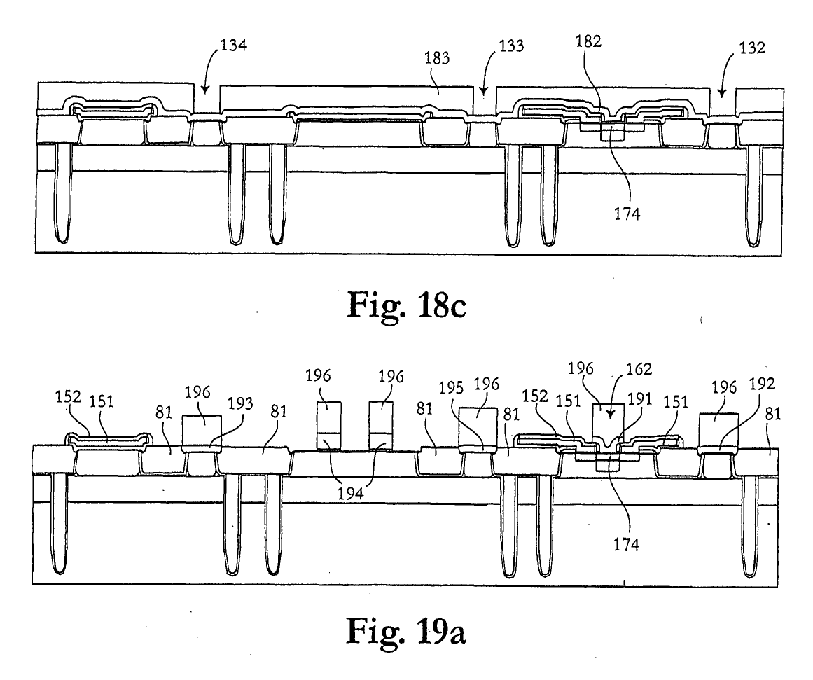

Then, with reference to FIG. 18a, an about 120 nm thick layer of silicon nitride is conformally deposited with LPCVD-technique. The nitride layer is etched by a special anisotropic etch until sidewall spacers 181 of silicon nitride remains where large steps at the surface exists, such as in the intrinsic base opening 162 for the NPN-transistor (inside spacers). After this spacer formation, the opening of the intrinsic base is henceforth referred to as the emitter opening 162. Not only the recently deposited nitride is removed, but also the thin nitride 141 (deposited in step 13) present on field 81 and collector contact areas 41 and on top of the PMOS gate structure 112 is simultaneously removed in this etch.

In the center of the emitter opening 162 there remains the thermal oxide, which also is to be removed. The oxide may be removed by wet or dry etching. In this particular example a two-step dry etch is used. The first etching step is oxide removal using RIE (Reactive Ion Etching) in a Ar/CHF₃/CF₄-plasma, and the second etching step is a mild isotropic silicon etch in situ in Ar/NF₃ to remove residues and radiation damage from the preceding RIE etch. The second etching step removes about 10 nm of silicon from the exposed area of the emitter opening. Since this etch affects the intrinsic base profile, the etch depth may be controlled depending on requirements on current gain (beta or h_{FE}) of the NPN-transistor to be manufactured.

This second etch will also remove part of the silicon used as first gate material 112 on the PMOS transistor. The initial thickness of the gate material has been selected with such a margin not to cause any problems for the PMOS transistor.

The resulting structure is shown in FIG. 18a.

After the etching, a polysilicon layer 182, typically 220 nm thick, is deposited using LPCVD-technique, see FIG. 18b. The layer 182 is subsequently doped by ion implantation, preferably arsenic and/or phosphorous.

In the preferred embodiment, the doping is performed in three separate steps.

Firstly, the whole surface of the wafer is implanted with arsenic at an energy of about 50 keV and a dose of 3E15 cm⁻².

Secondly, using a patterned photoresist mask (not illustrated), which leaves resist on area for resistors with low values (R_{LO}) and high values (R_{HI}), an arsenic implantation at an energy of about 150 keV and a dose of 1.2E16 cm⁻² is made. The resist mask is subsequently removed.

Thirdly, another mask layer 183, see FIG. 18c, which defines areas for low values resistors (R_{LO}), and for contact plug areas 132, 133, 134, is patterned, and then phosphorous at an energy of about 25 keV and a dose of 4E15 cm⁻² is implanted. The resist mask 183 is thereafter removed.

The high value resistors (R_{HI}) thus obtained will have a sheet resistivity of about 500 Ohms/square, while the low value resistors (R_{LO}) will have a sheet resistivity of about 100 Ohms/square. These resistance values can be changed by adjusting the doses and energies.

An important feature is that the polysilicon in contact with the emitter window receives two consecutive arsenic implants at different energies. No phosphorus is allowed to enter the emitter polysilicon 182, see FIG. 18c.

The polysilicon in contact with the collector, however, is typically implanted using a combination of arsenic and phosphorous. By use of two different dopant species of same doping type, but which have different diffusivities, a low-resistive and deeper collector contact is achieved.

19. Emitter Etch

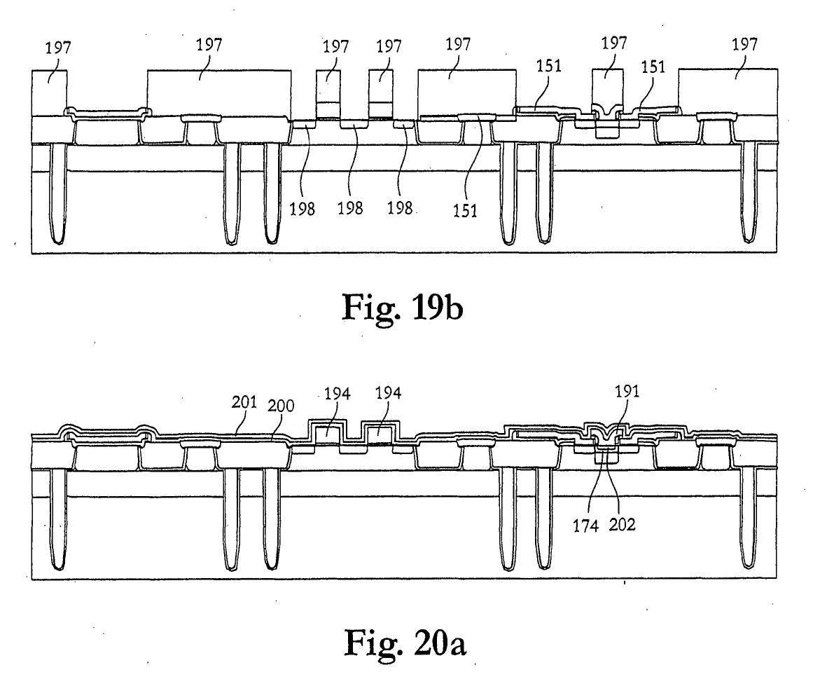

The doped polysilicon 182 (in FIG. 18c) will next be patterned using lithography and dry etching, see FIG. 19a. In this step, the contact areas to the emitter 191 and collector 192 of the NPN-transistor, the deeper electrode 193 of the nitride capacitor, the gates 194 of the PMOS-transistor and the substrate contact 195 of the PMOS-transistor, and low and high value resistors (not explicitly illustrated in FIG. 19a) are defined. Note that the illustrated PMOS device includes two PMOS transistors having thus two gate areas 194 (for fabrication of a quasi-lateral PNP device).

Where the polysilicon is in direct contact with the monocrystalline silicon surface in the emitter opening 162, the polysilicon will at a later process step operate as a doping source during the drive-in of the emitter in the intrinsic base region 174. Using photoresist mask 196, called EMI POLY mask, portions of the doped polysilicon is removed until the field oxide areas 81 are exposed. This etching is preferably done using RIE with a Cl₂/HBr/O₂ plasma.

The resulting structure is shown in FIG. 19a.

After the etch, resist is removed using conventional methods.

The oxide layer 152 on top of the p-type polysilicon layer 151 now has to be removed (not illustrated). This may be done by dry etching, either globally all over the wafer, or locally using a photo mask 197, called BASE OXREM mask, see FIG. 19b, which is the preferred approach in this embodiment. The photo mask is patterned such that openings are created over the p+ polysilicon layer. Then, the oxide is removed using RIE with an Ar/CHF₃/CF₄-plasma. The etching is stopped when the polysilicon is exposed in the resist openings. The advantage of using a photo mask, instead of a global etch, is that the field oxide areas 81 will be protected by the photoresist, otherwise they would have been eroded.

After etching, having resist still in place, an additional boron implant is performed to dope the respective source and drain areas 198 of the PMOS, see FIG. 19b. The extrinsic base 151 of the bipolar transistor, the top plate 151 of the capacitor, and polysilicon for p-type substrate contacts (not shown), will simultaneously be implanted. After completed etching and implantation, the photoresist is removed.

20. Emitter Activation and Drive-in

A thin, about 30 nm, oxide layer 200 is deposited on the wafer. Preferably TEOS is used, but another oxides, such a LTO or PECVD can alternatively be used.

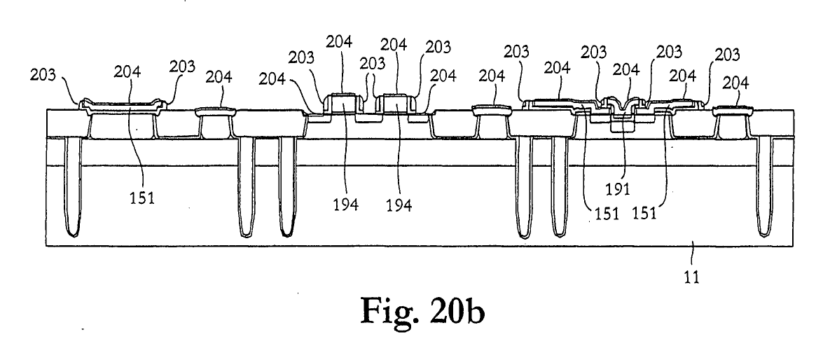

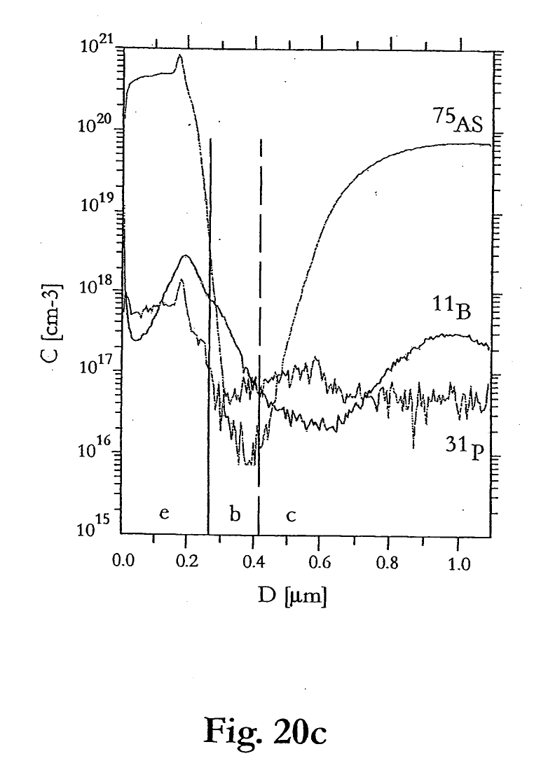

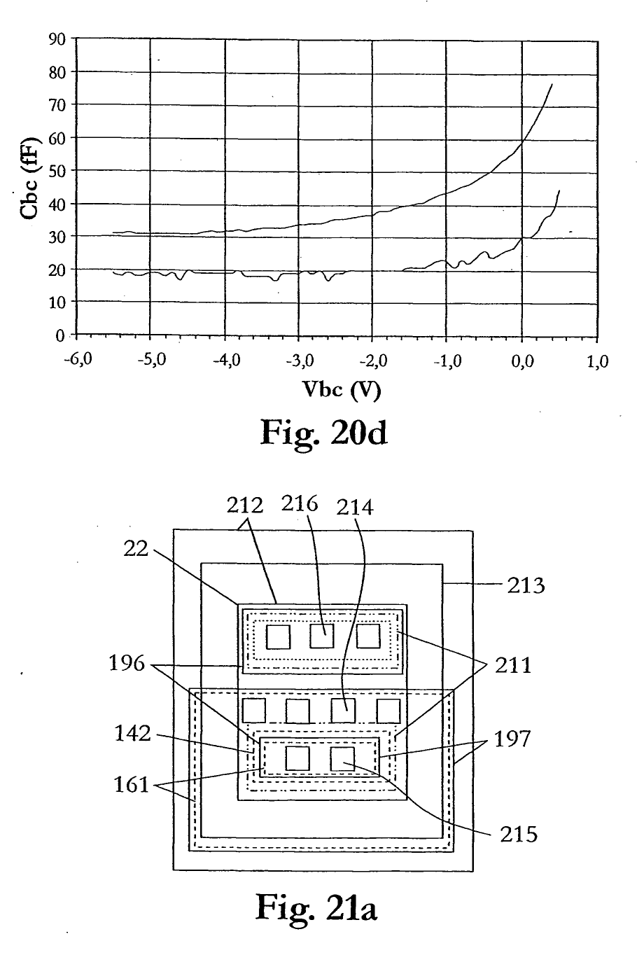

On top on the oxide 200, a silicon nitride layer 201 of about 100 nm thickness is conformably deposited using LPCVD-technique. The resulting structure is shown in FIG. 20a.

After the deposition, the wafer is exposed to high temperature to activate and drive-in the previously implanted dopants.

In the preferred embodiment, the heat treatment is performed in a two-step procedure. The wafer is first given a furnace anneal of 850° C. during about 30 minutes, which purpose is to redistribute the dopants more evenly in the implanted layers. This first step may in fact be dispensed with in the present process flow, since the semiconductor wafer already have received sufficient heat treatment during the deposition of the silicon oxide/nitride 200/201, which is typically performed at about 790° C. for more than three hours.

Secondly, another heat treatment in nitrogen at about 1075° C. during 16 seconds, using an RTA (Rapid Thermal Anneal) equipment is made. The purpose of this anneal is to electrically activate the implanted species, and to set the final doping profiles of the emitter-base junction of the NPN-transistor, and the profile of the PMOS device.

Note that the previously deposited silicon oxide 200 and silicon nitride 201 layer remain on the wafer. Their purpose is to stop out-diffusion of the implanted dopants to the surroundings during the heat treatment.

During the heat treatment, the arsenic, which was implanted in the upper n- poly layer 191, will by diffusion penetrate into the intrinsic base and form the emitter-base junction. For this embodiment, the depth of the emitter 202 is about 50 nm and the remaining thickness of the intrinsic base 174 under the emitter about 50 nm. The concentration of arsenic in the emitter opening at the junction between the surface of the monocrystalline silicon layer and the polycrystalline layer is typically 5E20 atoms/cm⁻³. The corresponding concentration of boron in the intrinsic base at the emitter-base junction is typically 1E18 atoms/cm⁻³.

At the same time, the boron, which was implanted in the extrinsic base contact poly layer, will diffuse and connect to the intrinsic base. For the described manufacturing process, the extrinsic base depth is about 200 nm, and the corresponding concentration of boron in the interface between the extrinsic base polysilicon and the monocrystalline silicon is typically 1E20 atoms/cm⁻³. This highly doped region of p-type is called extrinsic base.

The substrate contact is formed in a corresponding manner, by out-diffusion of boron from the polysilicon layer of p-type.

The gates 194 of the PMOS transistor structure consists of the n+ poly layer (182 in FIG. 18b), i.e. the emitter poly, and the remaining of the first gate material (112 in FIG. 11), which was undoped polysilicon. During the heat treatment, the n+ type dopants have redistributed in the gate layers by diffusion, such that the gates now are homogeneously doped with n+ material, and thus n+ gates 194 for the PMOS transistor have been formed.

The source/drains areas of the PMOS transistor are also activated by the heat treatment.

The resulting structure is shown in FIG. 20a.

After the annealing the resistor is lithographically defined, so that a protective layer of photoresist will remain only over the resistor bodies (not shown). End portions of the resistors will be exposed. After patterning the silicon nitride layer 201 and the silicon oxide layer 200 are etched away in the surface portions not covered by the photoresist layer. The etching is anisotropic, such that spacers 203 are formed along the edges of the polysilicon layer 194 of type N+, see FIG. 20b.

The process described herein in the manufacture of such so called spacers of silicon nitride on top of a thin silicon oxide layer is in substantial portions similar to the manufacturing process as described in U.S. Pat. No. 4,740,484 to H. Norström et al. Thereupon, the photoresist layer is removed.

After removing the photoresist layer, the polysilicon layer 194 of type N+ and the polysilicon layer 151 of type P+ can be provided with a thin silicide layer in order to reduce the resistance of conductors to the different electrode regions of the components to be manufactured—these conductors will then be shunted by such a silicide layer. This silicide layer can be constituted by e.g. PtSi, CoSi₂ or TiSi₂. In a preferred embodiment titanium disilicide TiSi₂ is used, which is formed using a so-called “self-aligning method” on top of exposed silicon surfaces. Since the resistor bodies are not exposed, but are protected by the remaining portions of the silicon nitride layer 201, no silicide is obtained thereon.

In such a self-aligned silicidation (“SALICIDE”), see U.S. Pat. No. 4,789,995 to Brighton et al. and U.S. Pat. No. 4,622,735 to Shibata, a thin metal layer is deposited, in this case a layer of titanium having a thickness of about 50 nm, preferably by sputtering, over the surface of the wafer. The metal layer is thereupon made to react for a short time, about 20 seconds, with exposed silicon at an elevated temperature of about 715 □C in a nitrogen gas atmosphere in an RTA-equipment. In certain cases also a mixture of oxygen gas and ammoniac can be employed. Thereafter, the titanium, which has not reacted with silicon, i.e. at those portions, which had no exposed silicon surface prior to the metal deposition, is solved away by wet chemical methods. This etching step, which selectively removes titanium, which has not reacted, affects the very titanium silicide only to a small extent. After the wet chemical etching process the plate is annealed at about 875 □C during about 30 seconds, such that a low resistive form of titanium disilicide is formed. The silicide layer thus produced, which has a surface resistance of about 2-5 ohms/square, will then only be present on the previously exposed silicon surfaces of the plate, i.e. be self-aligned with these surfaces.

The structure after outside spacer 203 formation and SALICIDE (self-aligned silicide) 204 formation is shown in FIG. 20b, and in FIG. 20c is shown a SIMS-profile for an NPN transistor fabricated in described process flow.

FIG. 20d displays the base-collector capacitance of a NPN transistor as a function of the base-collector voltage. The lower curve shows the capacitance for a NPN produced according to the inventive production process as described herein, whereas the upper curve shows the capacitance for an NPN transistor as produced with a prior art process using a thicker epi and a higher well-doping. Both the total capacitance value (represented by Cbc at 0 V Vbc) and less variation during the full range are obtained. Note that the transistor produced according to the invention fully depletes already at a bias voltage of about 1 V.

By carefully tuning the retrograde profile as described in U.S. Pat. No. 6,198,156 by Johansson and Arnborg, the linearity of the transistor can be further improved.

21. Mask Layouts, Contact Holes to First Metal Layer

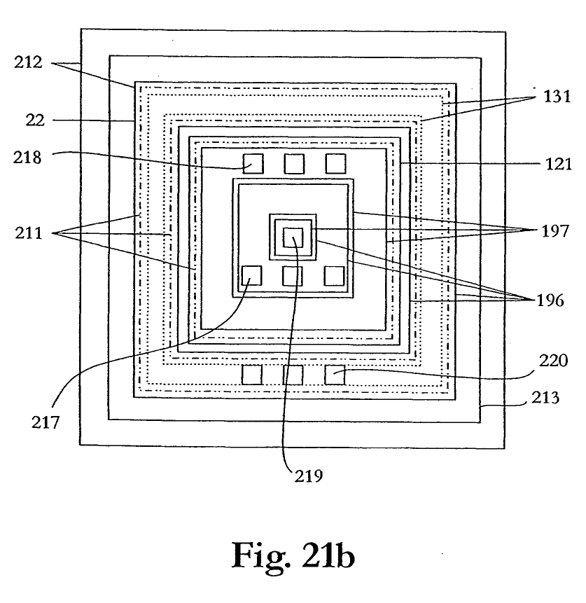

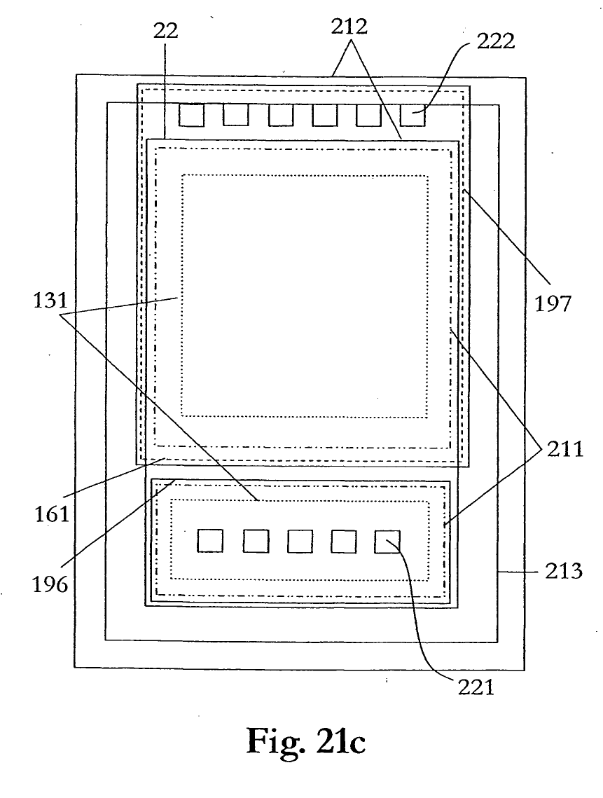

FIGS. 21a-c show mask layout views of the three main devices (NPN-transistor, a quasi-lateral PNP (i.e. the PMOS device) and the nitride capacitor), discussed in previous sections. The contact holes (chequered patterned) to the first metal layer are also shown.

In FIG. 21a masks for the NPN transistor is shown, where 22 is the SUB mask, 211 is the STI mask (see section 5), 212 is the deep trench mask (see section 6), 213 is the p-well mask (see section 9), 142 is the E/B mask, 161 is the REFEMIT mask, 196 is the EMI POLY mask, and 197 is the BASE OXREM mask.

Further, contact holes are illustrated for the base 214, for the emitter 215, and for the collector 216, respectively.

In FIG. 21b masks for the quasi-lateral PNP transistor is shown, where 22 is the SUB mask, 211 is the STI mask (see section 5), 212 is the deep trench mask (see section 6), 213 is the p-well mask (see section 9), 121 is the MOSBLK mask, 131 is the DNCAP mask, 196 is the EMI POLY mask, and 197 is the BASE OXREM mask. Note that the design of this component differs from the cross sectional views as also the substrate contact is formed of annular shape.

Further, contact holes are illustrated for the gate 217 (grounded), for the source 218 (collector) and drain 219 (emitter), and for the substrate contact 220 (base), respectively.

In FIG. 21c masks for the nitride capacitor is shown, where 22 is the SUB mask, 211 is the STI mask (see section 5), 212 is the deep trench mask (see section 6), 213 is the p-well mask (see section 9), 131 is the DNCAP mask, 161 is the REFEMIT mask, 196 is the EMI POLY mask, and 197 is the BASE OXREM mask.

Further, contact holes are illustrated for the upper 222 and lower 221 electrodes.

22. Connection to First Metal Layer

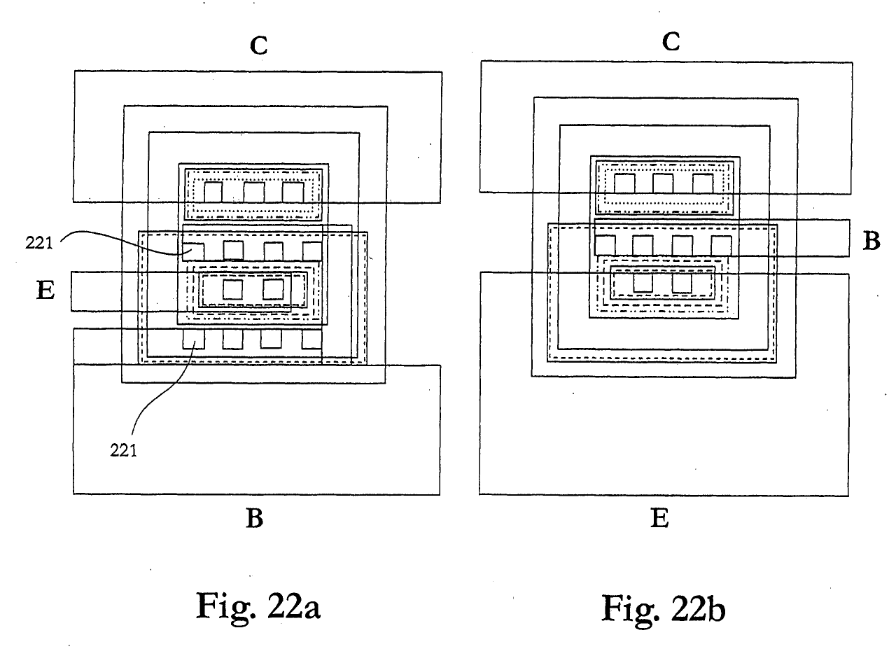

FIGS. 22a-b show an additional feature of the NPN transistor when connecting the transistor to the first metal layer.

To obtain a lowest base resistance (corresponding to the best frequency performance), base contacts 221 are placed on both sides of the emitter E, as shown in FIG. 22a. Thanks to the dense layout rules, this can be made without changing the size of the transistor (which is usually not the case in prior art processing methods).

However, some transistors in a circuit design may be used to output high currents. The layout in FIG. 22a may then be limited by the width of the metal contacting the emitter E (the current density in the emitter connection). Since the extrinsic base completely surrounds the emitter and is covered by TiSi₂ to further lower the base resistance, the metal connections would then be placed as shown in FIG. 22b, with only a very small increase of the base resistance.

Further, the same transistor layout can be used for double and single base contacts (only the contact holes and the metal layer have to be made differently).

The continued processing follows then essentially the process flow described in the international patent application published as WO 9903151 (inventors H. Norström, S. Nygren and O. Tylstedt).

If an NMOS device is to be manufactured in this process typically four more processing steps have to be added: masking and ion implantation of the NMOS gate region and masking and ion implantation of the NMOS source and drain regions.

Further, an MIM capacitor can be added to the flow as described in the international patent application published as U.S. Pat. No. 6,100,133 (inventors H. Norström and S. Nygren).

It will be obvious that the invention may be varied in a plurality of ways. Such variations are not to be regarded as a departure from the scope of the invention. All such modifications as would be obvious to one skilled in the art are intended to be included within the scope of the appended claims.

1. A method in the fabrication of an integrated circuit including at least one bipolar transistor and at least one MOS device comprising the steps of:
providing a silicon substrate;
forming an active region for the bipolar transistor and an active region for the MOS device in said silicon substrate;
forming field isolation areas around, in a horizontal plane, said active regions;
forming a MOS gate region on said active region for the MOS device;
forming a layer of an electrically insulating material on said MOS gate region and on said active region for the bipolar transistor; and
defining a base region in said active region for the bipolar transistor by means of producing an opening in said electrically insulating layer, wherein
said opening in said electrically insulating layer is produced so that the remaining portions of the electrically insulating layer partly cover said active region for the bipolar transistor; and
said electrically insulating layer remains on said MOS gate region to encapsulate and protect the MOS gate region during subsequent manufacturing steps.

2. The method as claimed in claim 1 wherein said electrically insulating layer is a nitride layer.

3. The method as claimed in claim 1 further comprising the step of manufacturing of a capacitor, wherein a portion of said electrically insulating layer is utilized as the dielectric in said capacitor.

4. The method as claimed in claim 1 wherein said MOS gate region is formed as a silicon layer on top of an oxide layer.

5. The method as claimed in claim 4 wherein an oxide is formed on top of the silicon layer prior to forming said electrically insulating layer.

6. The method as claimed in claim 4 further comprising the step of forming an oxide layer on top of said active region for the bipolar transistor prior to forming said electrically insulating layer.

7. The method as claimed in claim 6 further comprising the step of producing said opening also through said oxide layer on top of said active region so as to expose a portion of said active region for the bipolar transistor.

8. The method as claimed in claim 6 wherein said oxide layer, on top of which said gate polysilicon layer is formed, and said oxide layer formed on top of said active region for the bipolar transistor are formed simultaneously.

9. The method as claimed in claim 1 wherein said active region for the MOS device is ion implanted prior to the formation of said MOS gate region.

10. The method as claimed in claim 1 wherein a secondary implanted collector in said active region for the bipolar transistor and a background doping of said active region for the MOS device are formed simultaneously in an ion implantation step.

11. The method as claimed in claim 10 wherein an extrinsic base for the bipolar transistor is formed on said electrically insulating layer and partly on said active region for the bipolar transistor in said opening to thereby define an emitter opening, said extrinsic base being formed prior to said ion implantation step and being protected by photoresist during said ion implantation step.

12. The method as claimed in claim 11 wherein said extrinsic base is doped and source and drain regions are formed in said active region for the MOS device simultaneously in an ion implantation step.

13. The method as claimed in claim 12 wherein also an electrode of a capacitor or a contact layer for a substrate contact is doped in the ion implantation step, in which said extrinsic base is doped.

14. The method as claimed in claim 12 wherein a silicon oxide and silicon nitride bi-layer is formed on said doped source and drain regions to thereby prevent implanted species from diffusing out of said active region.

15. The method as claimed in claim 1 wherein said active regions for the bipolar transistor and the MOS device are formed by means of ion implantation through an oxide-nitride bi-layer.

16. The method as claimed in claim 1 wherein a collector including a collector plug for said bipolar transistor is formed, and wherein said collector plug is doped by means of ion implantation with two different dopant species of the same doping type, but which have different diffusivities, so as to achieve a low-resistive and deep collector plug.

17. The method as claimed in claim 16 wherein an emitter contact is formed, and wherein said emitter contact is doped with one of said dopant species used in said collector plug implantation.

18. The method as claimed in claim 16 wherein said ion implantation of the collector plug is performed in three separate steps, each step comprising the ion implantation of a dopant species at a set energy and a set dose.

19. The method as claimed in claim 18 wherein high resistance and low resistance resistors are formed in said three-step ion implantation.

20. The method as claimed in claim 1 wherein the bipolar transistor is an NPN-transistor and the MOS device is a PMOS transistor.

21. The method as claimed in claim 1 further comprising the steps of:
forming a buried collector region for the bipolar transistor in said substrate, said buried collector region being located underneath said active region for the bipolar transistor;
producing the field isolation area formed around the active region for the bipolar transistor as a shallow trench in said silicon substrate, said shallow trench extending vertically from the substrate surface and down into the buried collector region; and
filling said shallow trench with an electrically insulating material.

22. The method as claimed in claim 21 wherein said buried collector region and said shallow trench are formed relative each other so that said buried collector region extends into areas located underneath said shallow trench.

23. The method as claimed in claim 22 wherein said buried collector region is strongly n-doped.

24. The method as claimed in claim 21 wherein a deep trench is formed in said shallow trench.

25. The method as claimed in claim 1 wherein a vertical bipolar transistor is formed in said active region for the bipolar transistor, the doping profiles and heat treatment thereof being designed to produce a transistor, which will fully deplete from its base to its subcollector at a base-collector bias voltage larger than 2 V.

26. The method as claimed in claim 1 wherein a vertical bipolar transistor is formed in said active region for the bipolar transistor, the doping profiles and heat treatment thereof being designed to produce a transistor, which will fully deplete from its base to its subcollector at a base-collector bias voltage larger than 1 V.

27. The method as claimed in claim 25 wherein the collector is formed with a retrograde doping profile.

28. The method as claimed in claim 1 wherein said integrated circuit is an integrated circuit for radio frequency applications.

29. The method as claimed in claim 1 wherein said subsequent manufacturing steps include a step of oxidation, ion implantation, or etching.

30. The method as claimed in claim 8 wherein said oxide layer, on top of which said gate polysilicon layer is formed, and said oxide layer on top of said active region for the bipolar transistor are grown.

31. The method as claimed in claim 23 wherein said buried collector region is n-doped to a concentration of at least about 1E19 cm⁻³.

32. The method as claimed in claim 23 wherein said active region for the bipolar transistor is doped to a concentration not higher than about 1E17 cm⁻³.

33. The method as claimed in claim 23 wherein said active region for the bipolar transistor is doped to a concentration not higher than about 1E16 cm⁻³.

34. The method as claimed in claim 23 wherein said active region for the bipolar transistor is doped to a concentration of about 1E16 cm⁻³.

35. The method as claimed in claim 24 wherein said deep trench is self-aligned to said shallow trench.

36. In the fabrication of an integrated circuit, a method for forming a shallow trench for isolation of a vertical bipolar transistor comprised in said circuit, comprising the steps of:
providing a semiconductor substrate of a first doping type;
forming a buried collector region of a second doping type for the bipolar transistor in said substrate;
epitaxially growing a silicon layer on top of said substrate;
forming an active region of said second doping type for the bipolar transistor in said epitaxially grown silicon layer, the active region being located above the buried collector region;
forming a shallow trench in said epitaxially grown silicon layer and said silicon substrate, said shallow trench surrounding, in a horizontal plane, said active region and extending vertically a distance into said substrate; and
filling said shallow trench with an electrically insulating material.

37. The method as claimed in claim 36 wherein said buried collector region and said shallow trench are formed relative each other so that said buried collector region extends into areas located underneath said shallow trench.

38. The method as claimed in claim 36 wherein said shallow trench is formed by means of masking and etching.

39. The method as claimed in claim 36 wherein said substrate doping is of p-type and said buried collector region and said active region dopings are of n-type.

40. The method as claimed in claim 39 wherein said buried collector region is strongly n-doped.

41. The method as claimed in claim 36 wherein a deep trench is formed in said shallow trench.

42. The method as claimed in claim 36 wherein said integrated circuit is an integrated circuit for radio frequency applications.

43. The method as claimed in claim 40 wherein said buried collector region is doped to a concentration of at least about 1E19 cm⁻³.

44. The method as claimed in claim 40 wherein said active region is doped to a concentration not higher than about 1E17 cm⁻³.

45. The method as claimed in claim 40 wherein said active region for the bipolar transistor is doped to a concentration not higher than about 1E16 cm⁻³.

46. The method as claimed in claim 40 wherein said active region for the bipolar transistor is doped to a concentration of about 1E16 cm⁻³.

47. The method as claimed in claim 41 wherein said deep trench is self-aligned to said shallow trench.

48. An integrated circuit comprising:
a semiconductor substrate of a first doping type, said substrate having an upper surface;
a vertical bipolar transistor formed in said substrate, the transistor including an active region of a second doping type, wherein an emitter and a base are formed, and a buried collector region of said second doping type, said buried collector region being located underneath the active region; and
a shallow trench for isolation of the vertical bipolar transistor, wherein said shallow trench surrounds, as seen along the surface of the substrate, the active region of said transistor, and is filled with an electrically insulating material, wherein
said shallow trench extends vertically from the upper surface of the substrate and down into the substrate to a depth where said buried collector region is located.

49. The integrated circuit as claimed in claim 48 wherein said buried collector region extends into areas located underneath said shallow trench.

50. The integrated circuit as claimed in claim 48 wherein said buried collector region is strongly n-doped.

51. The integrated circuit as claimed in claim 48 wherein said integrated circuit is adapted for radio frequency applications.

52. The integrated circuit as claimed in claim 50 wherein said buried collector region is doped to a concentration of at least about 1E19 cm⁻³.

53. The integrated circuit as claimed in claim 50 wherein said active region is doped to a concentration not higher than about 1E17 cm⁻³.

54. The integrated circuit as claimed in claim 50 wherein said active region is doped to a concentration not higher than about 1E16 cm⁻³.

55. The integrated circuit as claimed in claim 50 wherein said active region is doped to a concentration of about 1E16 cm⁻³ .
